(19) United States
(12) Patent Application Publication
(10) Pub. No.: US 2018/0355201 A1
(43) Pub. Date: Dec. 13, 2018

(54) CIGS Nanoparticle Ink Formulation with a High Crack-Free Limit

(71) Applicant: Nanoco Technologies Ltd., Manchester (GB)

(72) Inventor: Cary Allen, Manchester (GB)

(21) Appl. No.: 16/001,698

(22) Filed: Jun. 6, 2018

Related U.S. Application Data
(60) Provisional application No. 62/516,366, filed on Jun. 7, 2017.

(51) Int. Cl. C09D 11/52; H01L 31/18; H01L 31/032; C09D 11/037; C09D 11/033

(52) U.S. Cl. CPC C09D 11/52; H01L 31/1864; C09D 11/033; C09D 11/037; H01L 31/0322

(57) ABSTRACT

A method for formulating a CIGS nanoparticle-based ink, which can be processed to form a thin film with a crack-free limit (CFL) of 500 nm or greater, comprises combining CIGS nanoparticles and binary chalcogenide nanoparticles in a solvent.

### CROSS-REFERENCE TO RELATED APPLICATIONS

This application claims the benefit of U.S. Provisional Patent Application No. 62/516,366 filed on Jun. 7, 2017, the contents of which are hereby incorporated by reference in their entirety.

### STATEMENT REGARDING FEDERALLY SPONSORED RESEARCH OR DEVELOPMENT

Not Applicable

### BACKGROUND OF THE INVENTION

### 1. Field of the Invention

The present invention generally relates to thin film photovoltaic devices. More particularly, it relates to copper indium gallium diselenide/disulfide (CIGS)-based thin film photovoltaic devices.

### 2. Description of the Related Art Including Information Disclosed Under 37 CFR 1.97 and 1.98

In order to be commercially viable, photovoltaic (PV) cells must generate electricity at a competitive cost to fossil fuels. To meet these costs, the PV cells must comprise low-cost materials along with an inexpensive device fabrication process and with moderate to high conversion efficiency of sunlight to electricity. In order for a device-building method to succeed, the materials synthesis and device fabrication must be commercially scalable.

At present, the photovoltaic market is still dominated by silicon wafer-based solar cells (first-generation solar cells). However, the active layer in these solar cells comprises silicon wafers having a thickness ranging from microns to hundreds of microns because silicon is a relatively poor absorber of light. These single-crystal wafers are very expensive to produce because the process involves fabricating and slicing high-purity, single-crystal silicon ingots, and is also very wasteful.

The high cost of crystalline silicon wafers has led the industry to look at less expensive materials to make solar cells and, for this reason, much development work has focused on producing high-efficiency thin film solar cells where material costs are significantly reduced compared to silicon.

Semiconductor materials like copper indium gallium diselenides and sulfides (Cu(In,Ga)(S,Se)₂, herein referred to as “CIGS”) are strong light absorbers and have band gaps that match well with the optimal spectral range for PV applications. Furthermore, because these materials have strong absorption coefficients the active layer in the solar cell need be only a few microns thick.

Copper indium diselenide (CuInSe₂) is one of the most promising candidates for thin film PV applications due to its unique structural and electrical properties. Its band gap of 1.0 eV is well-matched with the solar spectrum. CuInSe₂ solar cells can be made by selenization of CuInS₂ films because, during the selenization process, Se replaces S and the substitution creates volume expansion, which reduces void space and reproducibly leads to a high quality, dense CuInSe₂ absorber layers. [Q. Guo, G. M. Ford, H. W. Hillhouse and R. Agrawal, Nano Lett., 2009, 9, 3060] Assuming complete replacement of S with Se, the resulting lattice volume expansion is approximately 14.6%, which is calculated based on the lattice parameters of chalcopyrite (tetragonal) CuInS₂ (a=5.52 Å, c=11.12 Å) and CuInSe₂ (a=5.78 Å, c=11.62 Å). This means that the CuInS₂ nanocrystal film can be easily converted to a predominantly selenide material by annealing the film in a selenium-rich atmosphere. Therefore, CuInS₂ is a promising alternative precursor for producing CuInSe₂ or CuIn(S,Se)₂ absorber layers.

The theoretical optimum band gap for absorber materials is in the region of 1.2-1.4 eV. By incorporating gallium into CuIn(S,Se)₂ thin films, the band gap can be manipulated such that, following selenization, a CuₓIn_{y}Ga_{z}SₐSe_{b} absorber layer is formed with an optimal band gap for solar absorption.

Conventionally, costly vapor phase or evaporation techniques (for example metalorganic chemical vapor deposition (MO-CVD), radio frequency (RF) sputtering, and flash evaporation) have been used to deposit the CIGS films on a substrate. While these techniques deliver high quality films, they are difficult and expensive to scale to larger-area deposition and higher process throughput. Thus, solution processing of CIGS materials has been explored. One such approach involves depositing CIGS nanoparticles, which can be thermally processed to form a crystalline CIGS layer.

One of the major advantages of using CIGS nanoparticles is that they can be dispersed in a medium to form an ink that can be printed on a substrate in a similar way to inks in a newspaper-like process. The nanoparticle ink or paste can be deposited using low-cost printing techniques such as spin coating, slit coating and doctor blading. Printable solar cells may replace the standard conventional vacuum-deposited methods of solar cell manufacture because the printing processes, especially when implemented in a roll-to-roll processing framework, enable a much higher throughput.

The synthetic methods of the prior art offer limited control over the particle morphology, and particle solubility is usually poor which makes ink formulation difficult.

The challenge is to produce nanoparticles that overall are small, have a low melting point, narrow size distribution and incorporate a volatile capping agent, so that they can be dispersed in a medium and the capping agent can be eliminated easily during the film baking process. Another challenge is to avoid the inclusion of impurities, either from synthetic precursors or organic ligands that may compromise the overall efficiency of the final device.

U.S. Pat. No. 8,784,701 and commonly-owned U.S. patent application No. 61/772,372 [Nanoparticle Precursor for Thin-Film Solar Cells, filed 4 Mar. 2013] describe the synthesis of colloidal CIGS nanoparticles having a monodisperse size distribution, capped with organic ligands that enable solution processability and that can be removed at relatively low temperatures during thermal processing.

One of the challenges associated with the nanoparticle-based CIGS deposition approach is to achieve a high “crack-free limit” (CFL). The high organic content of colloidal CIGS nanoparticle-based ink formulations leads to large volume reduction when the as-deposited films are thermally processed. This reduction in volume can lead to cracking, peeling and delamination of the film. The critical thickness to which a film can be coated without this happening is known as the CFL. For colloidal CIGS nanoparticles, the CFL is typically about 100-150 nm, therefore ten or more coatings may be required to form a sufficiently thick film for a PV device.

Approaches to increase the CFL of colloidal nanoparticle films for optoelectronic device applications have been investigated. One such strategy is to reduce the organic content of the ink formulation, which can be achieved by synthesising nanoparticles with short-chain ligands or replacing the ligands with shorter chain functionalities, for example using a ligand exchange process. For example, Wills et al. reported the exchange of oleate ligands with shorter chain octyldithiocarbamate ligands on the surface of PbSe/CdSe core/shell nanoparticles to prepare more densely packed nanoparticle films. [A. W. Wills, M. S. Kang, A. Khare, W. L. Gladfelter and D. J. Norris, ACS Nano, 2010, 4, 4523] However, ligand exchange adds an extra processing step to the nanoparticle synthesis, and complete exchange can be difficult to achieve. Using the alternative approach of passivating the nanoparticle surface with short-chain ligands during colloidal synthesis requires changes to the reaction chemistry, and can lead to aggregation of the nanoparticles, rendering them poorly soluble.

In the ceramics industry, it is known that organic additives such as binders can be incorporated into a precursor solution to increase its CFL. However, this is unfavorable for CIGS nanoparticle films, since the organic additives may decompose to leave carbon residues within the film that can be detrimental to device performance. For example, Oda et al. reported a reduction in cracking of CuGaSe₂ films produced via an electro-deposition process with the addition of gelatin to the precursor solution. However, the post-annealing carbon concentration was found to increase with increasing gelatin concentration. [Y. Oda, T. Minemoto and H. Takakura, J. Electrochem. Soc., 2008, 155, H292] Further, in the preparation of solution-processed CIGS films, additives such as binders typically decompose at particle surfaces, which can impede grain growth. [T. Todorov and D. B. Mitzi, Eur. J. Inorg. Chem., 2010, 1, 17] An additional method used in the ceramics industry is to increase the drying time to prevent rapid film shrinkage, however this also increases the processing time.

Thus, there is a need for a method that increases the CFL of CIGS nanoparticle films, without substantially increasing the processing time or introducing components into the film that would be detrimental to device performance and/or impede grain growth.

### BRIEF SUMMARY OF THE INVENTION

A method is described to formulate a CIGS nanoparticle-based ink, which can be processed to form a thin film with a crack-free limit (CFL) of 500 nm or greater. Herein, the term “CIGS” should be understood to refer to any material of the general formula Cu_{w}InₓGa₁₋ₓSe_{y}S_{2-y}, where 0.1≤w≤2; 0≤x≤1 and 0≤y≤2, including doped species thereof. The method enables a CIGS layer with a thickness of 1 μm or greater to be deposited in just two coating steps, while maintaining a high quality, crack-free film. Further processing can be employed to form a photovoltaic device.

### BRIEF DESCRIPTION OF THE SEVERAL VIEWS OF THE DRAWING(S)

FIG. 1 shows a scanning electron micrograph (SEM) image of a CIGS layer deposited on a molybdenum-coated glass substrate according to embodiments of the Invention.

### DETAILED DESCRIPTION OF THE INVENTION

Herein, a method is disclosed for preparing a CIGS nanoparticle ink that can be deposited on a substrate and annealed to form a film with a thickness of 500 nm or greater, without cracking, peeling or delamination. By repeating the deposition and annealing processes, a film of 1 μm or greater can be deposited in two coating steps, with good adhesion between the two layers and to the underlying substrate, to form a homogeneous film. Further processing can be employed to fabricate a PV device. The high CFL enables a high-quality CIGS absorber layer to be formed in just two coating steps, reducing the labor intensity and processing time with respect to prior art nanoparticle-based deposition methods to form CIGS thin films. Using the current method, a crack-free limit of 500 nm or greater can be achieved without the addition of a binder to the ink formulation. The use of binders may be undesirable as they can decompose at the nanoparticle surface, impeding grain growth. A high film quality is desirable to optimize the performance characteristics of the PV device, such as the open-circuit voltage (V_{OC}), the short-circuit current (J_{SC}), the fill-factor (FF) and the overall power conversion efficiency (PCE).

The ink formulation comprises a combination of organic-capped CIGS nanoparticles and organic-capped binary Group 13 chalcogenide nanoparticles dissolved or dispersed in solution. As used herein, the term “binary Group 13 chalcogenide” refers to a compound of the form MₐX_{b}, wherein M is a Group 13 element, X is a Group 16 element, and a and b are >0. The organic ligands passivating the surface of the nanoparticles provide solubility, allowing the nanoparticles to be processed into an ink. The organic components of the ink formulation can be removed by thermal annealing at relatively low processing temperatures, well-within the PV device processing protocol. This enables carbon residues, which can be detrimental to device performance, to be removed from the film prior to sintering.

A selenization process can be employed to partially or completely convert Cu(In,Ga)S₂ and/or binary sulphide nanoparticles to Cu(In,Ga)Se₂, to form either a Cu(In,Ga)(S,Se)₂ or Cu(In,Ga)Se₂ absorber layer. A selenization process may also be desirable in order to grow large grains, which are desirable since the recombination of charge carriers is promoted at grain boundaries. Thus a grain size on the order of the absorber layer thickness is desirable to maximize the PCE of the photovoltaic device.

In one embodiment, the CIGS nanoparticles have a copper-rich stoichiometry, wherein Cu/(In+Ga)>1. In combination with InSe and/or InS and/or GaSe and/or GaS nanoparticles (or alloys thereof), this can be used to tune the band gap of the CIGS absorber layer. The inherent chemical composition of the nanoparticles, i.e., the Cu:In:Ga ratios, may be manipulated during nanoparticle synthesis.

### Description of One Particular Preparative Procedure According to the Invention.

According to certain embodiments, a CIGS device is prepared from CIGS nanoparticles and binary sulphide nanoparticles as follows:
a) Dissolve/disperse CIGS nanoparticles in a solvent, to form an ink, A.
b) Dissolve/disperse binary indium chalcogenide nanoparticles in a solvent to form an ink, B.
c) Dissolve/disperse binary gallium chalcogenide nanoparticles in a solvent to form an ink, C.
d) Combine inks A, B and C to form an ink, D.
e) Deposit the ink, D, on a substrate to form a film.
f) Anneal in an inert atmosphere.
g) Repeat steps e) and f), until the annealed film reaches the desired thickness.
h) Perform further film processing steps, e.g., annealing, sintering, selenization, KCN etching, as required.
i) Deposit an n-type semiconductor layer to form a junction.
j) Deposit intrinsic ZnO to form an extended depletion layer.
k) Deposit a window layer.
l) Deposit a metal grid.
m) Encapsulate the device.

The preparation of solution-processable Cu(In,Ga)(S,Se)₂ nanoparticles is described in U.S. Pat. No. 8,784,701, U.S. Pat. No. 9,466,743 and U.S. patent application publication number 2015/0136213, the contents of which are hereby incorporated by reference in their entireties. The preparation of binary selenide nanoparticles is described in U.S. Pat. No. 9,359,202, the contents of which is hereby incorporated by reference in its entirety.

### EXAMPLES

Preparation of Cu-Rich CIGS Nanoparticles

Cu-rich Cu(In,Ga)S₂ nanoparticles were prepared according to U.S. Patent Application Publication No. 2015/0136213, which is hereby incorporated by reference in its entirety. The nanoparticles were capped with 1-octanethiol and oleylamine, and the ratio of Cu:In:Ga (as determined by inductively-coupled plasma analysis) was 1.414:0.665:0.335.

Preparation of InS Nanoparticles

An oven-dried 250-ml round bottom flask (RBF) was charged with 8.109 g In(OAc)₃, 1.5 g S powder, 24 ml oleylamine (≥98% primary amine), and 30 ml dibenzyl ether (Bz₂O). The flask was fitted with a stillhead and collector and the mixture degassed at 100° C. for 30 minutes before being backfilled with N₂.

28 ml of degassed 1-octanethiol were added and the mixture was heated to 200° C. for 2 hours before being allowed to cool to 160° C. and left to stir overnight.

After annealing at 160° C. for ˜18 hours, the flask was opened to the atmosphere and then 20 ml toluene/100 ml methanol were added. The mixture was spun at 2700 G for 5 minutes and the supernatant was discarded. The resulting solid was dispersed in 50 ml toluene and the mixture spun at 2700 G for 5 minutes. The supernatant was set aside and the remaining residue discarded.

30 ml of methanol were added and the mixture spun at 2700 G for 5 minutes. The supernatant was discarded and the resulting solid was dispersed in 25 ml toluene. The mixture was spun at 2700 G for 3 minutes and the supernatant transferred to a glass vial. The remaining residue was discarded.

The InS nanoparticles were dissolved in toluene and stored under air.

Preparation of GaS Nanoparticles

An oven-dried 250-ml RBF was charged with 10.786 g Ga(acac)₃, 1.5 g S powder, 24 ml oleylamine (≥98% primary amine), and 30 ml Bz₂O. The flask was fitted with a stillhead and collector and the mixture degassed at 100° C. for 30 minutes before being backfilled with N₂.

28 ml of degassed 1-octanethiol were added and the mixture was heated to 200° C. for 2 hours before being allowed to cool to 160° C. and left to stir overnight.

After annealing at 160° C. for ˜18 hours the flask was opened to the atmosphere then 20 ml toluene/300 ml methanol were added. The mixture was spun at 2700 G for 5 minutes and the supernatant was discarded. 50 ml of propan-2-ol were added to the oily red product and the mixture shaken vigorously before being spun at 2700 G for 5 minutes. The supernatant was discarded and the resulting solid dispersed in 35 ml toluene. The mixture was spun at 2700 G for 5 minutes and the supernatant set aside. Remaining residue was discarded.

30 ml propan-2-ol/70 ml methanol were added and the mixture spun at 2700 G for 5 minutes. The supernatant was discarded and the resulting oily product was rinsed with 20 ml propan-2-ol. The product was isolated by centrifugation and the supernatant discarded. The resulting solid was dispersed in 20 ml toluene and the mixture spun at 2700 G for 3 minutes. The supernatant was transferred to a glass vial and any remaining residue discarded.

The GaS nanoparticles were dissolved in toluene and stored under air.

Preparation of a CIGS/InS/GaS Ink

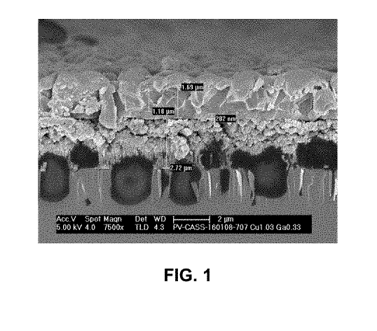

Cu-rich CIGS nanoparticles dissolved in toluene (5 mL, 1150 mg), InS nanoparticles dissolved in toluene (1 mL, 200 mg), and GaS nanoparticles dissolved in toluene (389 μL, 70 mg) were combined to form an ink. The ink was deposited and a CIGS device formed according to methods described in U.S. Patent Application Publication No. 2015/0136213. A crack-free film with a thickness of 1637 nm was deposited from two layers on top of an adhesion layer. The use of an adhesion layer is described in Applicant's co-pending U.S. patent application Ser. No. 15/412,827, which is hereby incorporated by reference in its entirety. FIG. 1 shows a scanning electron micrograph (SEM) image of a CIGS layer deposited on a molybdenum-coated glass substrate according to the above procedure.

What is claimed is:

1. An ink formulation having a crack-free limit (CFL) of 500 nm or greater, comprising:
a CIGS nanoparticle;
a binary chalcogenide nanoparticle; and
a solvent.

2. The ink formulation recited in claim 1 wherein the CIGS nanoparticle has the formula:
Cu_{w}InₓGa₁₋ₓSe_{y}S_{2-y}, where 0.1≤w≤2; 0≤x≤1; and 0≤y≤2.

3. The ink formulation recited in claim 1 wherein the binary chalcogenide nanoparticle has the formula:
MₐX_{b}
where M is a Group 13 element, X is a Group 16 element, and a and b are >0.5.

4. The ink formulation recited in claim 1 wherein the binary chalcogenide nanoparticle is InS.

5. The ink formulation recited in claim 1 wherein the binary chalcogenide nanoparticle is InSe.

6. The ink formulation recited in claim 1 wherein the binary chalcogenide nanoparticle is GaS.

7. The ink formulation recited in claim 1 wherein the binary chalcogenide nanoparticle is GaSe.

8. The ink formulation recited in claim 1 wherein the CIGS nanoparticle has a copper-rich stoichiometry.

9. The ink formulation recited in claim 1 wherein the atomic ratio Cu/(In+Ga) of the CIGS nanoparticle is greater than one.

10. The ink formulation recited in claim 1 wherein the solvent is toluene.

11. The ink formulation recited in claim 1 wherein the CIGS nanoparticle is capped with 1-octanethiol and oleylamine.

12. The ink formulation recited in claim 1 wherein the ink formulation is free of any added binder.

13. An ink formulation having a crack-free limit (CFL) of 500 nm or greater, consisting essentially of:
CIGS nanoparticles dissolved in toluene wherein the atomic ratio Cu/(In+Ga) of the CIGS nanoparticles is greater than one;
InS nanoparticles dissolved in toluene; and
GaS nanoparticles dissolved in toluene.

14. A process for preparing a CIGS-based photovoltaic device comprising:
a) dissolving/dispersing CIGS nanoparticles in a solvent, to form an ink, A;
b) dissolving/dispersing binary indium chalcogenide nanoparticles in a solvent to form an ink, B;
c) dissolving/dispersing binary gallium chalcogenide nanoparticles in a solvent to form an ink, C;
d) combining inks A, B and C to form an ink, D;
e) depositing the ink, D, on a substrate to form a film;
f) annealing the film in an inert atmosphere;
g) repeating steps e) and f), until the annealed film reaches a desired thickness.

15. The process recited in claim 14 wherein the CIGS nanoparticles have the formula:
Cu_{w}InₓGa₁₋ₓSe_{y}S_{2-y}, where 0.1≤w≤2; 0≤x≤1; and 0≤y≤2.

16. The process recited in claim 14 wherein the solvent is toluene.

17. The process recited in claim 14 wherein the binary indium chalcogenide nanoparticles are selected from the group consisting of InS and InSe.

18. The process recited in claim 14 wherein the binary gallium chalcogenide nanoparticles are selected from the group consisting of GaS and GaSe.

19. The process recited in claim 14 wherein steps e) and f) are repeated only once and the annealed film reaches a thickness of at least 1 μm.

20. The process recited in claim 14 wherein the substrate is a molybdenum-coated glass substrate.
